(19) United States
(12) Patent Application Publication
(10) Pub. No.: US 2013/0257832 A1
(43) Pub. Date: Oct. 3, 2013

(54) IMAGE PICKOFF APPARATUS SYSTEM AND METHOD

(71) Applicant: JOHN BARNETT HAMMOND, Roanoke, VA (US)

(72) Inventor: JOHN BARNETT HAMMOND, Roanoke, VA (US)

(73) Assignee: EXELIS, INC., MCLEAN, VA (US)

(21) Appl. No.: 13/435,003

(22) Filed: Mar. 30, 2012

(51) Int. Cl. H01L 27/146; G09G 5/10

(52) U.S. Cl. 345/207; 250/208.1; 250/338.1; 250/341.8

(57) ABSTRACT

Image apparatus, eyewear, and imaging methods are disclosed. The image apparatus may include a waveguide substrate having a viewing region and a detecting region. The viewing region includes a plurality of parallel partially reflective surfaces. Light from a scene may be received in the viewing region of the waveguide substrate with a portion passed through the viewing region and another portion reflected toward the detecting region of the waveguide substrate. The detecting region may direct the other portion toward a detector.

### BACKGROUND OF THE INVENTION

Night vision systems are used in a wide variety of military, industrial and residential applications to enable sight in a dark environment. For example, night vision systems are utilized by military aviators during nighttime flights or military soldiers patrolling the ground.

Conventional night vision systems utilize light beam pick offs created using common cube type beam splitters or flat plate splitters. The splitters pick off a percentage of the incoming beams of light, allowing the rest to pass through for viewing by a user of the night vision system.

Systems that use cube type beam splitters are bulky and heavy and systems that use flat plate splitters often possess image aberrations.

### SUMMARY OF THE INVENTION

The present invention is embodied in image apparatus, eyewear, and imaging methods. The image apparatus may include a waveguide substrate having a viewing region and a detecting region. The viewing region includes a plurality of parallel partially reflective surfaces. Light from a scene may be received in the viewing region of the waveguide substrate with a portion passed through the viewing region and another portion reflected toward the detecting region of the waveguide substrate. The detecting region may direct the other portion toward a detector.

### BRIEF DESCRIPTION OF THE DRAWINGS

The invention is best understood from the following detailed description when read in connection with the accompanying drawings, with like elements having the same reference numerals. When a plurality of similar elements are present, a single reference numeral may be assigned to the plurality of similar elements with a small letter designation referring to specific elements. When referring to the elements collectively or to a non-specific one or more of the elements, the small letter designation may be dropped. The letter “n” may represent a non-specific number of elements. Also, lines without arrows connecting components may represent a bi-directional exchange between these components. This emphasizes that according to common practice, the various features of the drawings are not drawn to scale. On the contrary, the dimensions of the various features are arbitrarily expanded or reduced for clarity. Included in the drawings are the following figures:

FIG. 1 is a top view of an image apparatus in accordance with aspects of the present invention;

FIG. 2 is a top view of another image apparatus in accordance with aspects of the present invention;

FIG. 3 is a illustrative view of a technique for forming a waveguide substrate for use in the image apparatus of FIG. 1;

FIG. 4 is a top view of eyewear incorporating the image apparatus of FIG. 1;

FIG. 5 is a flow chart depicting steps for enabling a user to view a scene and to capture the viewed scene in accordance with aspects of the present invention;

FIG. 6 is a flow chart depicting steps for projecting an image for viewing along with the scene using the steps of FIG. 5 in accordance with aspects of the present invention;

FIG. 7 is a top view of another image apparatus that tracks eye movements in accordance with another aspect of the present invention; and

FIG. 8 is a flow chart depicting steps for tracking eye movement in accordance with aspects of the present invention.

### DETAILED DESCRIPTION OF THE INVENTION

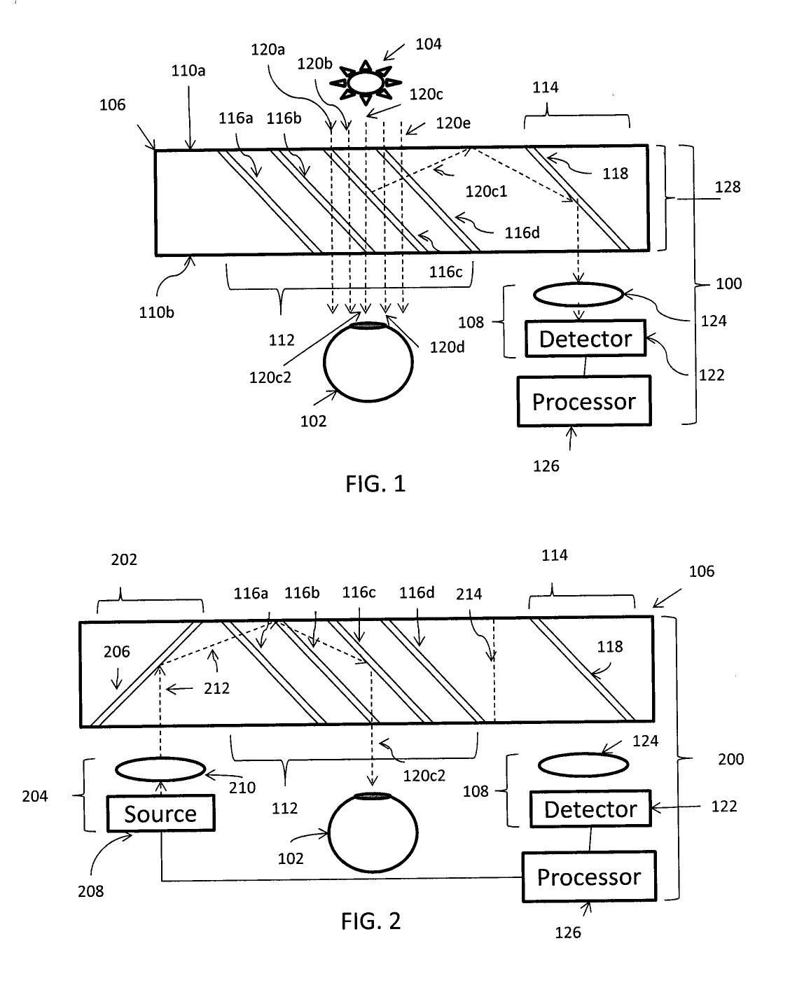

FIG. 1 depicts an image apparatus 100 in accordance with aspects of the present invention that enables an eye 102 of a user to view a scene 104 and that captures the viewed scene substantially simultaneously.

Image apparatus 100 includes a waveguide substrate 106 and an is imager 108. The waveguide substrate 106 has a first planar surface 110a and a second planar surface 110b spaced from and parallel to the first planar surface 110a. The waveguide substrate 106 includes a viewing region 112 and a detecting region 114. The viewing region 112 includes a plurality of parallel partially reflective surfaces 116 and the detecting region 114 includes at least one reflective surface 118. In one embodiment, the at least one reflective surface 118 is parallel to each of the plurality of partially reflective surfaces 116. As used herein the term parallel is meant to include relationships between structures that are substantially parallel, e.g., within about plus or minus 5 degrees.

The scene 104 radiates beams of scene light 120 that enter the waveguide substrate 106 through the first planar surface 110a. The partially reflective surfaces 116 partially reflect a first portion of the beams of scene light 120 toward the detecting region 114 while allowing a second portion of the beams of scene light 120 to pass thorough the waveguide substrate 106 and out of the second planar surface 110b for viewing by the eye 102 of the user. For example, when beam of scene light 120c strikes a partially reflective surface, a first portion 120c1 is reflected toward detecting region 114 and a second portion 120c2 is allowed to pass though for viewing by the eye 102 of the user.

Although four partially reflective surfaces are illustrated (i.e., partially reflective surfaces 116a-d), it will be understood that the number of partially reflective surfaces is dependent on the area of the viewing region 112. A suitable number of partially reflective surfaces and their orientation within the waveguide substrate 106 will be understood by one of skill in the art from the description herein. The partially reflective surfaces may be designed to pass a first percentage of scene light 120 and reflect a second percentage of scene light (e.g., through the use of coatings on the partially reflective surfaces and/or the structure of the partially reflective surfaces). For example, the partially reflective surfaces may pass approximately 80% of the scene light (e.g., 78% for Lumus 0E-32) and reflect approximately 20% (e.g., 22% for Lumus 0E-32).

The at least one reflective surface 118 in the detecting region 114 reflects at least a portion (e.g., substantially all) of the second portion out of the waveguide 106 where it is detected by the imager 108. The imager 108 may include a detector 122 and a lens 124 for focusing light received from the waveguide substrate 106 onto the detector 122. In the illustrated embodiment, the imager 108 is positioned adjacent to the second planar surface 110b of the substrate 106 and the at least one reflective surface 118 is positioned within the waveguide substrate 106 to direct the second portion out of the second planar surface 110b of the waveguide. In alternative embodiments, the imager 108 may be positioned adjacent to the first planar surface 110a of the substrate 106 and the at least one reflective surface 118 is positioned within the waveguide substrate 106 to direct the second portion out of the first planar surface 110a of the waveguide. In other alternative embodiments, the imager 108 may be positioned adjacent to the edge 128 of the waveguide substrate 106, in which case the at least one reflective surface 118 may be omitted.

A processor 126 coupled to the imager 108 processes the light detected by the imager 108. Suitable processors 122 and imagers 108 for use with the present invention will be understood by one of skill in the art from the description herein.

FIG. 2 depicts an image apparatus 200 in accordance with aspects of the present invention that enables an eye 102 of a user to view a scene 104, that captures the viewed scene substantially simultaneously, and that projects an image onto the eye 102. The structure of image apparatus 200 is similar to image apparatus 100 described above with reference to FIG. 1 with the addition of a projecting region 202 to the waveguide substrate 106 and a projector 204. Common components between the imaging apparatus 100/200 are similarly numbered and are not discussed again in detail.

The projecting region 202 includes at least one other reflective surface 206 that reflects at least a portion (e.g., substantially all) of the light received from the projector 204 into the waveguide 106. The projector 204 may include a source 208 and a lens 210 for focusing light from the source 208 into the waveguide 106. Light from the projector 204, represented by light beam 212, is directed toward the other reflective surface 206 within the projecting region 202 of the waveguide 106. After reflection into the waveguide 106, the light beam 212 is internally reflected within the waveguide 106 until it reaches the plurality of parallel partially reflective surfaces 116.

The plurality of partially reflective surfaces 116 reflect at least a portion of the image light beam 212 out of the waveguide 106 such that it is combined with the scene light beam 120c2 for viewing by the eye 102 of the user/viewer.

In one embodiment, the plurality of reflective surfaces 116 may include a coating and the wavelengths for the image light may be selected such that substantially all the image light 212 is reflected out of the waveguide by the partially reflective surfaces 116 and, thus, the image light does not pass though the substrate 106 to the viewing region 114, where it could deteriorate the quality of scene image light. In accordance with this embodiment, the image light may be monochromatic or polychromatic. In the monochromatic embodiment, the partially reflective surfaces may be configured to reflect all of that monochromatic image light. In the polychromatic embodiment, the image light will be polychromatic and filtered to produce a polychromatic image. In another embodiment, an optional filter 214 is positioned between the viewing region 112 and the detecting region to block portions of light from the projecting region 202 (e.g., based on a selected frequency) that passed through the plurality of parallel partially reflective surfaces 116. In another embodiment, image light from the projecting region 202 that passes through the viewing region 112 to the detecting region may be accommodated by the processor 126 (e.g., by subtracting the image light out).

In the illustrated embodiment, the projector 204 is positioned adjacent to the second planar surface 110b of the substrate 106 and the at least one other reflective surface 208 is positioned within the waveguide substrate 106 to direct the light from the projector 204 into the waveguide 106. In alternative embodiments, the projector 204 may be positioned adjacent to the first planar surface 110a of the substrate 106 and the at least one other reflective surface 208 is positioned within the waveguide substrate 106 to direct the light from the projector 204 into the waveguide 106.

The processor 126 may additionally be coupled to the projector 204. In accordance with this embodiment, the processor 126 may process the light detected by the imager 108 and generate an image for projection by the projector 204. Suitable projectors 204 for use with the present invention will be understood by one of skill in the art from the description herein.

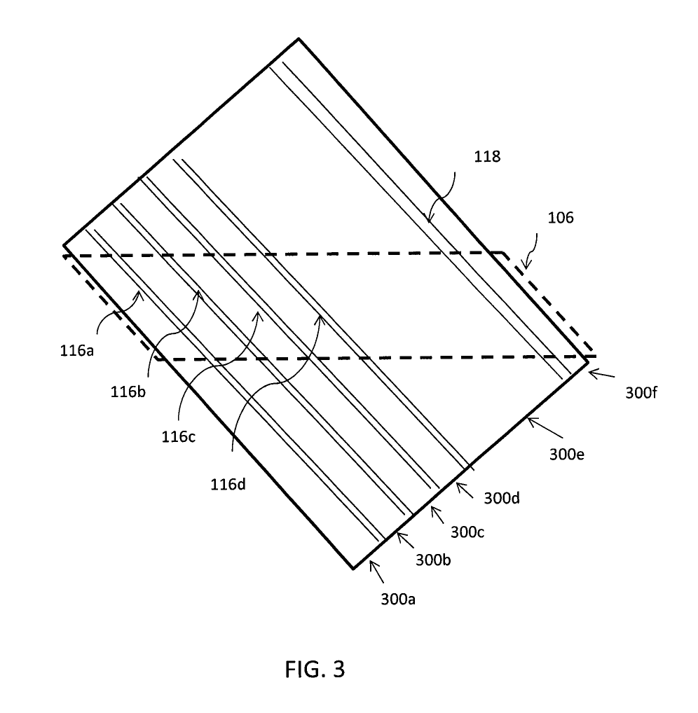

FIG. 3 illustrates a technique for making a waveguide substrate 106 including a plurality of parallel partially reflective surfaces 116 and at least one reflective surface 118. In the illustrated embodiment, the at least one reflective surface 118 is substantially parallel to each of the plurality of partially reflective surfaces 116. The surfaces 116/118 may be formed at the intersection of one or more pieces of substrate base material 300 (e.g., a silica based material such as BK-7, Pyrex, and/or a polymer material such as Polycarbonate). One or more coatings may be applied between the layers of base material to adhere the layers to one another and achieve the desired reflection profiles. For example, different coatings may be applied between base material 300d and 300e than between 300e and 300f such that partially reflective surface 116d is partially reflective and the at least one reflective surface 118 is substantially reflective. The coatings may be wavelength dependent such that different wavelengths of light experience different amounts of reflectance at one or more of the surfaces 116/118. The waveguide substrate 106 may then be cut (e.g., along horizontal dashed lines) from the stack of base materials 300 using known cutting, grinding, and polishing techniques to form the waveguide substrates 106.

In one embodiment, the waveguide substrate 106 is a total internal reflection (TIR) waveguide. Although one internal reflection is illustrated for detected scene light (e.g., light beam 120c1; FIGS. 1 and 2) and for projected image light (e.g., light beam 212; FIG. 2), it will be understood that additional reflections may occur between the viewing region and each of the detecting region 114 and the projecting region 202. Suitable materials for the waveguide substrate 106 will be understood by one of skill in the art from the description herein. Additional details regarding waveguide substrates that may be modified for use with the present invention in a manner that will be understood by one of skill in the art may be found in U.S. Pat. No. 6,829,095 to Amitai for a SUBSTRATE-GUIDED OPTICAL BEAM EXPANDER, which is incorporated fully herein by reference.

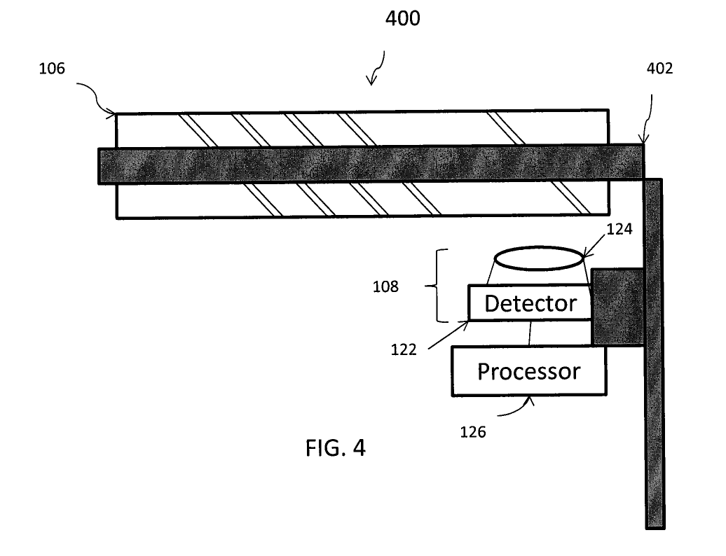

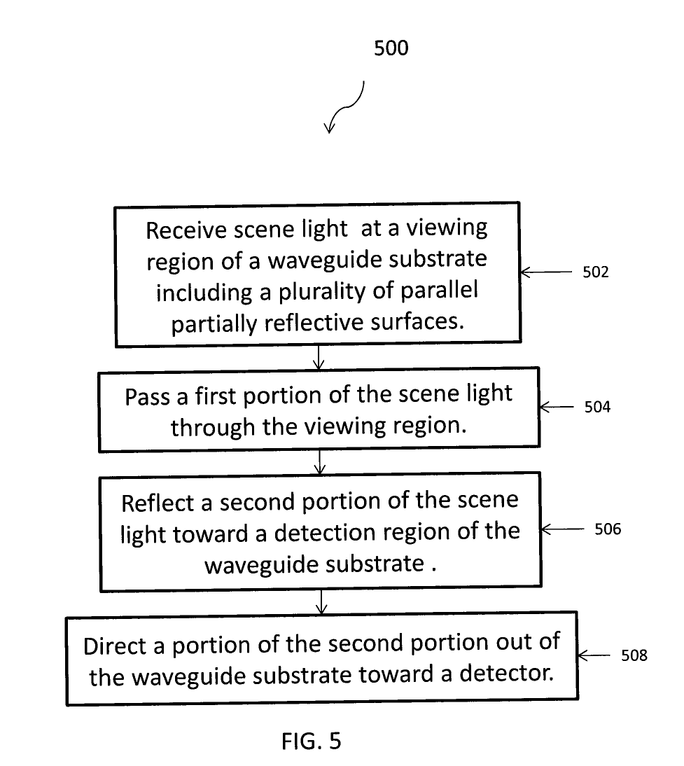

FIG. 4 depicts eyewear 400 in accordance with an aspect of the present invention. The illustrated eyewear 400 includes a frame 402 that supports the waveguide substrate 106, the imager 108, and the processor 126. It will be understood that the frame 402 could be further configured to support the projector 204 and a substrate including the projecting region 202. In one embodiment, the frame is a helmet mounted frame such as those used for night vision applications. Due to the light weight nature of the waveguide substrate 106, significant improvements in weight over conventional systems using cube type beam splitters are achievable.

FIG. 5 depicts a flow chart 500 of exemplary steps in accordance with aspects of the present invention that enables a user to view a scene and that captures the viewed scene substantially simultaneously. The method is described below with reference to FIGS. 1 and 2.

At block 502, scene light from an image/scene is received in a viewing region of a waveguide substrate. The viewing region includes a plurality of parallel partially reflective surfaces. Scene light 102 from scene 104 may be received in viewing region 112 of waveguide substrate 106 where viewing region includes a plurality of parallel partially reflective surfaces 116.

At block 504, a first portion of the scene light passes through the viewing region of the waveguide substrate. The plurality of partially reflective surfaces 116 may allow a first portion of the scene light 120c2 to pass through the waveguide substrate 106 from the first planar surface 110a and out through the second planar surface 110b for viewing by the eye 102 of the viewer.

At block 506, a second portion of the scene light is reflected toward a detecting region of the waveguide substrate. The plurality of partially reflective surfaces 116 may reflect a second portion of the scene light 120c1 toward the detecting region 114 of the waveguide substrate 106.

At block 508, at least a portion of the second portion of scene light is directed out of the detecting region of the waveguide substrate toward a detector. The at least one reflective surface 118 in the detecting region 114 may reflect substantially all of the second portion of scene light out of the waveguide substrate 106 toward the detector 108.

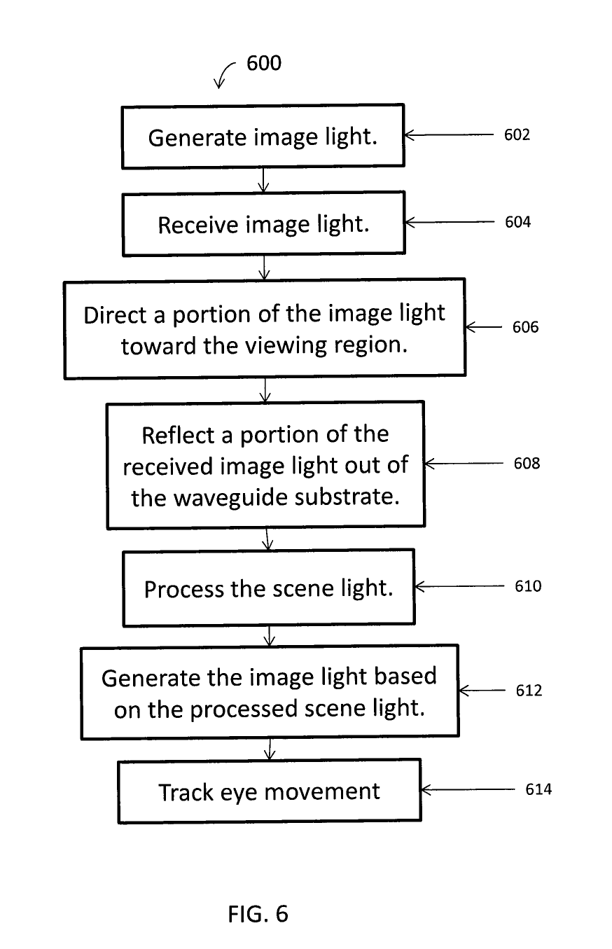

FIG. 6 depicts optional steps for use with the method of FIG. 5 to additionally project an image for viewing by the eye 102 of the viewer. The method is described below with reference to FIG. 2.

At block 602, image light is generated. Image light may be generated and projected toward waveguide substrate 602 by projector 204.

At block 604, image light is received in the waveguide substrate. The image light may be received in a projecting region 202 of the waveguide substrate 106.

At block 606, a portion of the received image light is directed toward the viewing region. The at least one other reflective surface 208 in the projecting region 208 may direct the image light toward the plurality of parallel partially reflective surfaces 116 in the viewing region 112 of the waveguide substrate 106.

At block 608, at least a portion of the portion of the received image light is reflected out of the waveguide substrate. The plurality of partially reflective surfaces 116 in the viewing region 112 of the waveguide substrate 106 may reflect at least a portion of the image light received from the at least one other reflective surface 208 out of the viewing region 112 of the waveguide substrate 106 for viewing by an eye 102 of the viewer.

At block 610, the reflected portion of the second portion of scene light is processed. Processor 126 may process the reflected portion of the second portion of the scene light.

At block 612, the image light is generated based on the processed scene light. The processor 126 may control projector 204 to generate the image light based on the scene light.

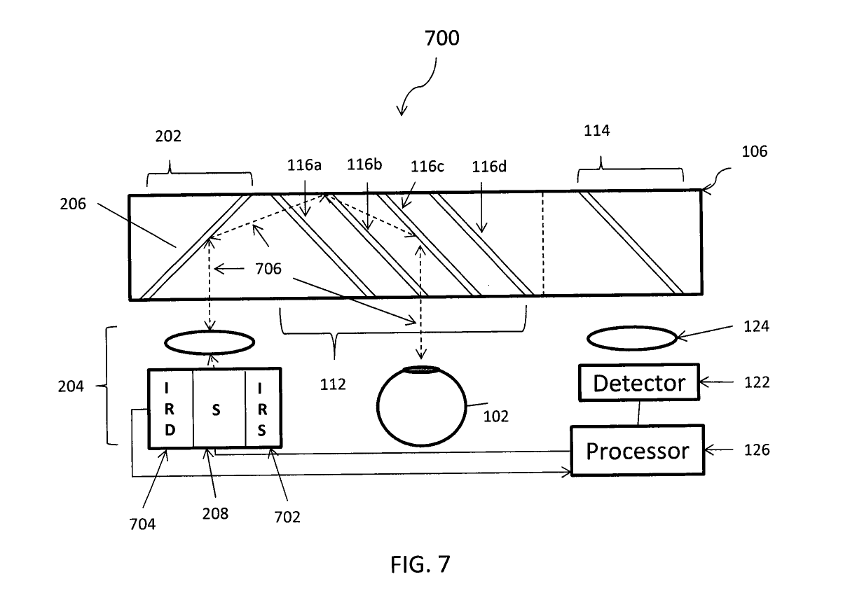

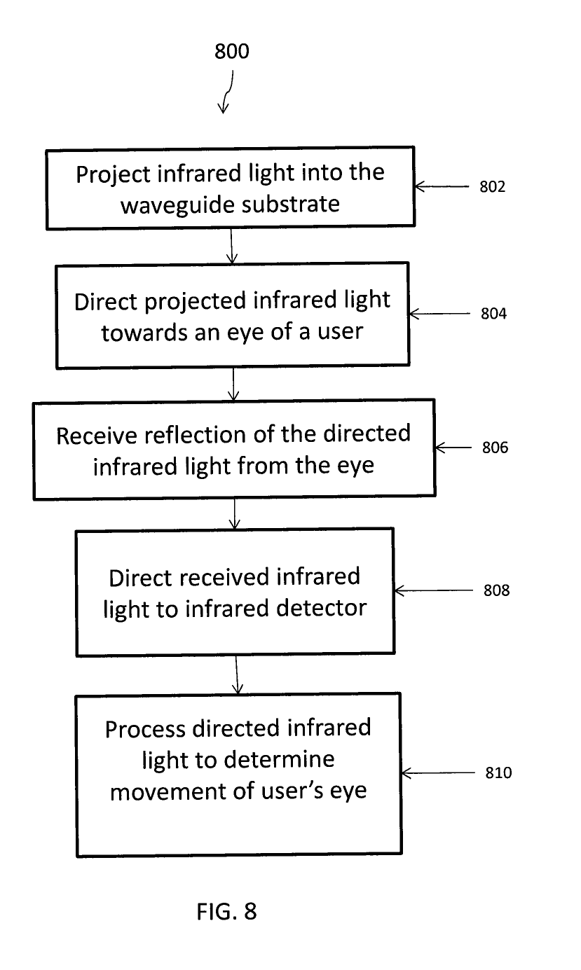

At block 614, movement of the eye 102 is optionally tracked. Embodiments for tracking eye movements are described below with reference to FIG. 7 and FIG. 8.

FIG. 7 depicts an image apparatus 700 in accordance with aspects of the present invention that enables the tracking of an eye 102 of a user. The structure of image apparatus 700 is similar to image apparatus 100 and image apparatus 200 described above with reference to FIG. 1 and FIG. 2. Apparatus 700 adds an infrared source 702 and infrared detector 704 that transmit and receive infrared light 706, respectively. Common components between imaging apparatuses 100/200 and 700 are similarly numbered and are not discussed again in detail.

Infrared source 702 directs infrared light 706 to the projecting region 202. Projecting region 202 includes at least one reflective surface 206 that reflects at least a portion (e.g., substantially all) of the infrared light 706 received from the infrared source 702 into the waveguide substrate 106. The infrared light 706 is directed towards the eye 102 of a user by way of a plurality of partially reflective surfaces 116.

The infrared light is then reflected from the eye 102 of a user (e.g., by the retina). The plurality of partially reflective surfaces 116 reflect the reflected infrared light 706 towards the projecting region 202. The projecting region 202 receives the reflected infrared light 706 and directs it out of the waveguide substrate 106 by way of the at least one reflective surface 206. The infrared detector 704 receives the infrared light 706 and directs the received infrared light 706 towards processor 126 to determine movement of the eye 102 of the user.

FIG. 8 depicts steps for use with the method of FIG. 6 to track the eye movement of a user in accordance with embodiments of the present invention. The method is described below with reference to FIG. 7.

At block 802, infrared light is projected into the waveguide substrate. Infrared source 702 may project infrared light 706 into the waveguide substrate 106.

At block 804, at least a portion of the projected infrared light is directed towards an eye of a user. The at least one reflective surface 206 may reflect at least a portion of the projected light from the projecting region 202 to the viewing region 112. At least a portion of this reflected infrared light 706 may be directed out of the waveguide substrate 106 and towards the eye 102 of a user.

At block 806, a reflection of the directed infrared light from the eye 102 is received. At least a portion of the reflected infrared light 706 may be reflected from the eye 102 of a user. The infrared light 706 reflected from the eye 102 of a user may be directed into the waveguide substrate 106.

At block 808, the received infrared light is directed to the infrared detector. The at least one reflective surface 206 may reflect the infrared light 706 out of the waveguide substrate 106 and toward the infrared detector 704.

At block 810, directed infrared light is processed to determine movement of the user's eye. The processor 126 may process the infrared light 706 received by the detector 704 to determine movement of the eye 102 of a user.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. An image apparatus, the apparatus comprising:
a waveguide substrate having a first planar surface that receives scene light representing a scene and a second planar surface parallel the first planar surface, the waveguide substrate including a viewing region and a detecting region, the viewing region including a plurality of parallel partially reflective surfaces; and
an imager positioned adjacent to the detecting region.

2. The apparatus of claim 1, wherein the plurality of parallel partially reflective surfaces receive the scene light from the first planar surface in the viewing region, pass a first portion of the received scene light toward the second planar surface, and reflect a second portion of the received scene light toward the detecting region.

3. The apparatus of claim 1, wherein the detecting region includes at least one reflective surface.

4. The apparatus of claim 3, wherein the at least one reflective surface reflects at least a portion of the second portion of the received scene light toward the imager.

5. The apparatus of claim 3, wherein the at least one reflective surface is parallel to each of the plurality of parallel partially reflective surfaces.

6. The apparatus of claim 3, wherein the waveguide substrate further includes:
a projecting region including at least one other reflective surface, wherein the at least one other reflective surface receives image light from the second planar surface in the projecting region and reflects at least a portion of the received image light toward the plurality of parallel partially reflective surfaces in the viewing region.

7. The apparatus of claim 6, wherein the plurality of parallel partially reflective surfaces reflect at least a portion of the portion of the received image light toward the second planar surface in the viewing region.

8. The apparatus of claim 6, the apparatus further comprising:
a projector positioned adjacent to the image projecting region.

9. The apparatus of claim 8, further comprising:
an infrared source positioned adjacent to the image projecting region; and
an infrared detection positioned adjacent to the image projecting region.

10. The apparatus of claim 6, wherein the plurality of parallel partially reflective surfaces reflect substantially all of the reflected portion of the received image light.

11. The apparatus of claim 6, wherein the produced image light is monochromatic and the plurality of parallel partially reflective surfaces are configured to reflect substantially all of the monochromatic image light.

12. The apparatus of claim 6, wherein the received image light is polychromatic and the plurality of parallel partially reflective surfaces are configured to reflect substantially all of the polychromatic image light.

13. The apparatus of claim 6, further comprising:
a filter positioned between the image viewing region and the detecting region that is configured to block the reflected received image light from reaching the viewing region.

14. The apparatus of claim 6, further comprising:
a frame coupled to the waveguide substrate and the image.

15. The apparatus of claim 8, further comprising:
a processor coupled between the detector and the projector, the processor processing the scene light received by the detector and controlling generation of the image light based on the processed scene light.

16. The apparatus of claim 1, wherein the waveguide substrate is a total internal reflection waveguide substrate.

17. An image detection method, the method comprising:
receiving scene light from a scene at a viewing region of a waveguide substrate, the viewing region including a plurality of parallel partially reflective surfaces;
passing a first portion of the scene light through the viewing region of the waveguide substrate;
reflecting a second portion of the scene light toward a detecting region of the waveguide substrate with the plurality of parallel partially reflective surfaces;
directing at least a portion of the second portion of scene light out of the detecting region of the waveguide substrate toward a detector.

18. The method of claim 17, further comprising:
receiving image light from a projector at a projecting region of the waveguide substrate;
directing at least a portion of the received image light toward the plurality of parallel partially reflective surfaces in the viewing region of the waveguide substrate; and
reflecting at least a portion of the portion of the received image lights out of the waveguide substrate in the viewing region of the waveguide substrate.

19. The method of claim 18, further comprising:
processing the reflected portion of the second portion of scene light; and
generating the image light based on the processed reflected portion of the second portion of scene light.

20. The method of claim 17, further comprising:
tracking an eye of a user

21. The method of claim 20, wherein the tracking step comprises:
projecting infrared light into the waveguide substrate;
directing at least a portion of the projected infrared light through the waveguide substrate and out of the waveguide substrate 106 towards the eye;
receiving a reflection of the directed infrared light from the eye with the waveguide substrate;
directing the received infrared light to an infrared detector; and
processing the directed infrared light detected by the infrared detector to determine movement of the eye of a user.
